(19) United States
(12) Patent Application Publication
(10) Pub. No.: US 2012/0038577 A1
(43) Pub. Date: Feb. 16, 2012

(54) FLOATING PLANE TOUCH INPUT DEVICE AND METHOD

(75) Inventors: Daniel BROWN, Newark, CA (US); Krystyna MALINIAK, San Francisco, CA (US); Frank N. CAPONE, Danville, CA (US)

(73) Assignee: FLOATINGTOUCH, LLC, Danville, CA (US)

(21) Appl. No.: 13/210,300

(22) Filed: Aug. 15, 2011

Related U.S. Application Data
(60) Provisional application No. 61/374,148, filed on Aug. 16, 2010.

(51) Int. Cl. G06F 3/041; H05K 7/00

(52) U.S. Cl. 345/173; 248/309.1; 248/201; 178/18.01

(57) ABSTRACT

A touch input device and method for manufacturing a touch input device are described. Each embodiment includes a touch surface, a mounting fixture, a sensing-suspension system, and a locating system. The touch surface may be an integral component of a host system, such as a display, which would result in a touch screen, or a touchpad input device. The touch surface is a floating plane, where the suspension positions, attaches and motion-enables the touch surface within the host system, and where the force exerted on the touch surface causes displacement of the touch surface, which motion is interpreted to calculate a touch location.

### CROSS-REFERENCE TO RELATED APPLICATIONS

This application claims the benefit of U.S. Provisional Application No. 61/374,148, filed on Aug. 16, 2010, entitled “FLOATING-PLANE TOUCH INPUT DEVICE AND METHOD,” which is incorporated herein by reference in its entirety.

### FIELD OF THE INVENTION

The present invention generally relates to electronic devices and methods and more particularly to a method and system for providing touch input to an electronic device.

### BACKGROUND

Touch screens are finding increasing use for providing input to electronic devices. Most current touch systems resort to an overlay film using capacitive or resistive technology. These films use intersecting rows and columns of wires to locate a touch by its physical position, making it costly to maintain fine resolution on ever-larger screen dimensions. Touch screens produced this way have limitations, including a clean-room overlay process that adds cost and reduces the transmissivity of displays.

Force-based touch systems operate by detecting a force applied to a touch surface and have the potential to be less costly, but practical devices run into difficulties requiring additional complexity.

One problem encountered in prior art force-based touch screens is that each touch on the screen imparts multiple force vectors (in all three axes), depressing in the Z-axis while also sliding or shifting sideways in the X-Y axes (in the plane of the screen). These lateral force vectors inevitably diminish and displace some portion of every touch force, which has been the primary obstacle to force-based touch designs. Managing or compensating for these lateral sheer-forces along the X-Y axes represents a significant problem that plagues prior art force-based systems.

Another problem of force-based touch systems is that they require adding an apparatus comprising sensors, a mounting frame 12 and a touch cover surface above the host display screen 14 (as shown in FIG. 1). This adds cost, weight, thickness and complexity to the host device. Following is a list of problems that arise in various attempts to produce force-based touch devices:
Friction and other interfering lateral forces are difficult to detect and complex to counteract;
Accuracy and sensitivity are impaired by interfering forces;
Host or external vibrations can cause distortion and inaccuracy of touch location when rigid mounting systems are employed;
Extraneous components are often required to compensate for lateral force vectors, increasing cost and complicating the manufacturing of such devices;
Extraneous components enlarge the device (e.g., stack-height), complicating miniaturization;
A complicated mechanism may be required to keep surfaces co-planar; and
Extremely small tolerances are required during manufacturing.

The problem of lateral force vectors has resulted in complex devices, directly contradicting that original promise of economy. Due to the daunting mechanical challenges, there are very few examples of successful force-based touch devices. Still, the promise of force-based touch screens remains due to their relative economy and potentially unlimited resolution.

Thus there is a need in the art for a method and apparatus that enables the simple construction and operation of a force-based touch system. Such a method and apparatus should be economical, compatible with standard or conventional electronic devices, and should be easy to incorporate into electronic devices.

### BRIEF SUMMARY OF THE INVENTION

In certain embodiments, a floating touch-plane input device is provided which includes a mounting material that “floats” the touch surface in a manner that accommodates X-Y friction and notably improves detection of Z-forces, while avoiding mechanical complexity.

In yet other certain embodiments, a force-based touch input device integrates the fluidic mounting and touch sensing functions to motion-enable the touch surface and determine the Z-axis distance changes between the touch surface and the host device while avoiding a detectable position shift of the touch surface, thus diminishing unwanted lateral forces and easing assembly tolerances.

In certain embodiments, a force-based touch input device employs floating sensing-mounts, or a modular floating sub-assembly of sensing-mounts to replace the existing internal static display mounting with a floating sensing-mount system, and thereby motion-enable the LCD display itself as the touch surface. This eliminates external touch frame and cover glass (as shown in FIG. 1), provides 100% display-image transmission to the user, and avoids extra major component costs or additional bulk, thereby implementing a very thin touch device. The touch surface may commonly be an integral component of the device, such as a display panel or cathode-ray tube, which would result in a touch screen without adding any extra planes or thickness to the device. Absent the display, this method can result in a touchpad input device.

In certain other embodiments, a force-based touch input device is provided having a multiplicity of sensors arrayed symmetrically or asymmetrically in any locations beneath the touch surface, or above its perimeter, thus enabling higher levels of detection accuracy, greater screen resolution, and multi-touch sensitivity.

A force-sensing touch input device implemented as described here gains the use of Z-axis readings, and therefore is capable of interpreting all touch sources, such as finger, glove, or stylus and capable of interpreting pressure commands via pressure-gestures.

These features together with the various ancillary provisions and features which will become apparent to those skilled in the art from the following detailed description are attained by the floating sensing-mount touch input system of the present invention, embodiments thereof being shown with reference to the accompanying drawings, by way of example only.

### BRIEF DESCRIPTION OF THE DRAWINGS

FIG. 1 is a prior art drawing that illustrates a touch frame and cover glass apparatus implemented over top of a host display;

FIG. 2A is a perspective and an exploded view of a multi-plate capacitive sensing-mount.

FIG. 2B is a perspective and an exploded view of a parallel plate capacitive sensing-mount.

FIG. 3A is a perspective view of a plurality of sensing-mounts arrayed randomly.

FIG. 3B is an exploded view of the randomly arrayed sensing-mounts of FIG. 3A.

FIG. 4 is an exploded view of a sensing-module.

FIG. 5 is an exploded view of a multi-layer sensing-module.

FIGS. 6A-6C illustrates pressure-gestures that are enabled by sensing-module implementations.

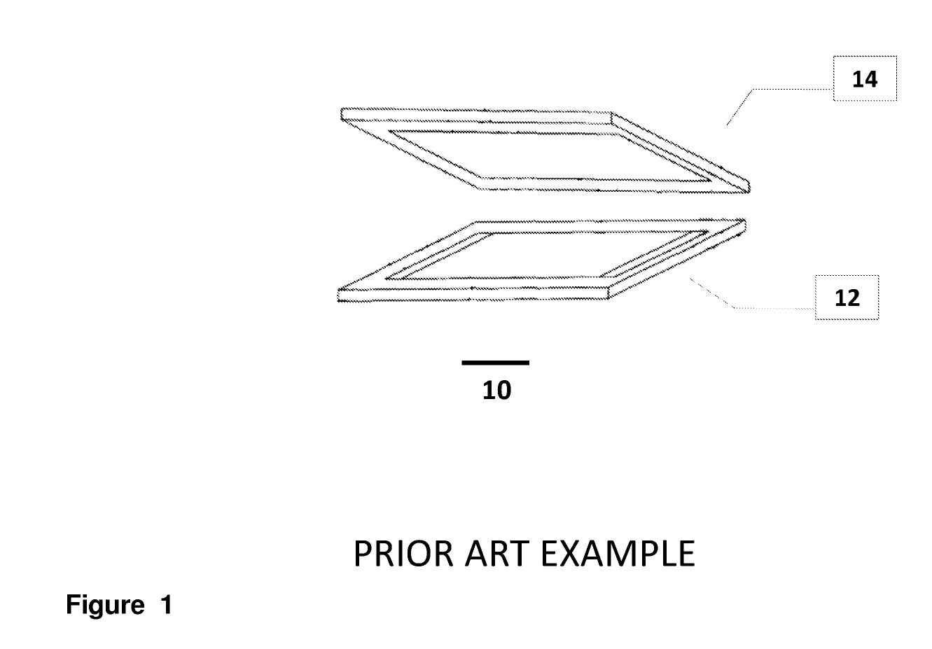

Reference symbols are used in the Figures to indicate certain components, aspects or features shown therein, with reference symbols common to more than one Figure indicating like components, aspects or features shown therein.

### DETAILED DESCRIPTION OF THE INVENTION

The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

A system and method in accordance with the present invention specifies an integrated, flexible “sensing-suspension” to separate, affix and motion-enable (collectively, to “float”) a touch surface relative to its host device, all representing the “suspension” function. When the user touches the touch surface, an integrated sensing framework (representing the “sensing” function) detects and measures displacement changes in the touch surface, while providing minimal impact on those changes. A locating system analyzes those changes to calculate the location of a touch and report to the host system.

Displacement or deflection motion of the touch surface occurs due to the Z-axis force imparted during a touch event. This force is detected by the sensing framework as readings of distance changes at each sensing location. Because this invention relies on Z-axis force, it detects all touch sources, finger, glove, or stylus, as examples and without limitation.

The suspension system, as defined subsequently, is configured to float or suspend a touch surface relative to its host device, and couple them together. The suspension materials may contact the touch surface and host device over the entire or a substantial part of the touch surface, around some or the entire touch surface perimeter, at several discrete locations at the perimeter or at a more interior location beneath the touch surface.

The sensing-mount, as defined subsequently, integrates any among a multiplicity of sensing technologies with specified suspension materials to accomplish an integrated sensing-suspension. The sensing-mount is the smallest integrated component of the sensing-suspension concept. A sensing-mount may be implemented as an array of three or more individual point-mounts, or conceptually implemented in pre-manufactured suspension arrays, as a suspension module or sub-assembly, termed the suspension pad.

The combination of touch surface, host device, and suspension enables a slight “floating” motion of the touch surface when touched, which then returns to the original resting position when the touch is removed. The host device may be, for example and without limitation, a cell phone, tablet/reader, or computer display.

The following is a general discussion of components and/or aspects, any one of which may be present in embodiments of a floating plane touch screen.

### Touch Surface

In certain embodiments, the touch surface may be, for example and without limitation, a display panel, a protective cover glass over a display (e.g., kiosk cabinet), or a non-display touch panel, for use as a touchpad or digitizing pad. A typical electronic host device employs a flexible adhesion material for mounting an LCD display, termed here as an idle or static mounting system. The floating sensing-mount system integrates motion sensors into a flexible mounting system. Sensing-mounts may be arrayed beneath an LCD or CRT display to motion-enable it, thereby adapting said existing display as a touch input surface, while avoiding the cost, weight and thickness of additional components.

### Sensing-Suspension System

The suspension system is a configuration of components to couple or attach a touch surface and its host device, and to provide a resting position of the touch surface, termed here the “attachment” function. The suspension system also enables the touch surface to move (primarily in the Z-axis) in response to any force, and then restores its original position when the force is removed, termed here the “floating” function.

A flexible polymeric material may be formulated to compensate for lateral shift (X-Y sheer vectors) of the touch surface, and to redirect any lateral forces downward into the vertical Z-axis, which is essential for touch detection accuracy. In an embodiment a flexible acrylic foam material possesses this redirection property, as well as the fluidic and synergistic properties described herein as necessary or valuable.

The suspension system positions, attaches and motion-enables (collectively, “floats”) the touch surface, and may be implemented, for example and without limitation, in at least one of the following ways:

A discrete point mount method disposes sensing-mounts beneath a touch surface at several individual mounting points, symmetrically or randomly arrayed as dictated by the host system design. Sensing-mounts are necessary to provide the discrete point mounts.

A plane must be supported at three or more points. Accordingly, individual sensing-mounts must be disposed at three or more discrete mounting points to support a touch surface, to locate a touch, and to enable a floating plane touch input device.

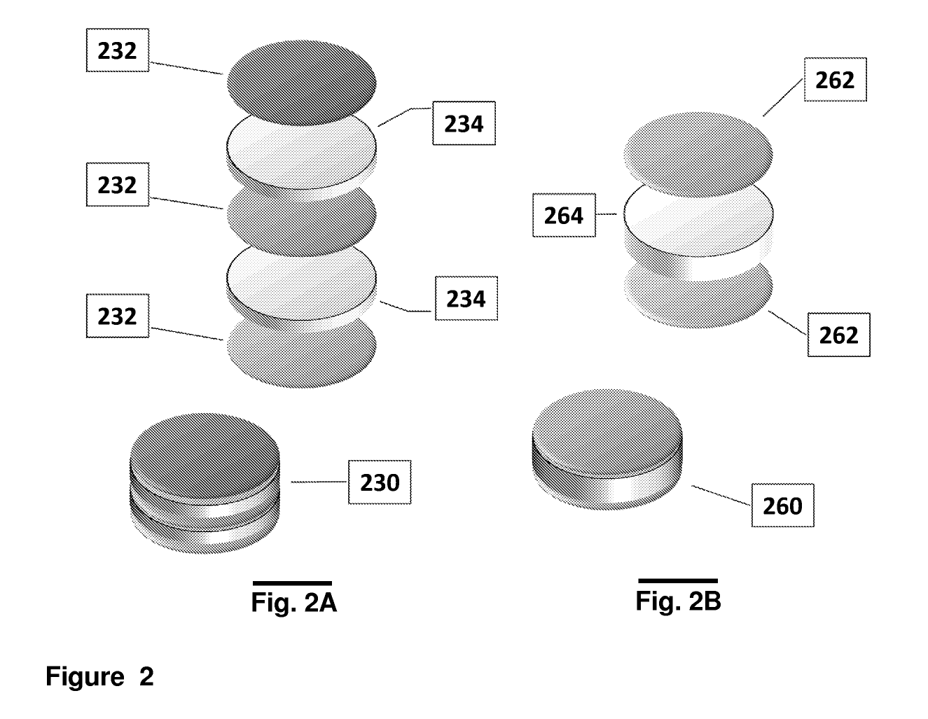

FIG. 2A is a perspective and exploded view of a multi-plate capacitive sensing-mount. In this embodiment, the sensing-mount 230 comprises three conductive members 232 separated by two flexible suspension members 234.

FIG. 2B is a perspective and an exploded view of a parallel plate capacitive sensing-mount. In this embodiment, the sensing-mount 260 comprises a first and second conductive members 262 separated by one flexible suspension member 264. Individual sensing-mounts, capacitive parallel-plate and multi-plate, are depicted in FIGS. 2A and 2B as examples and without limitation.

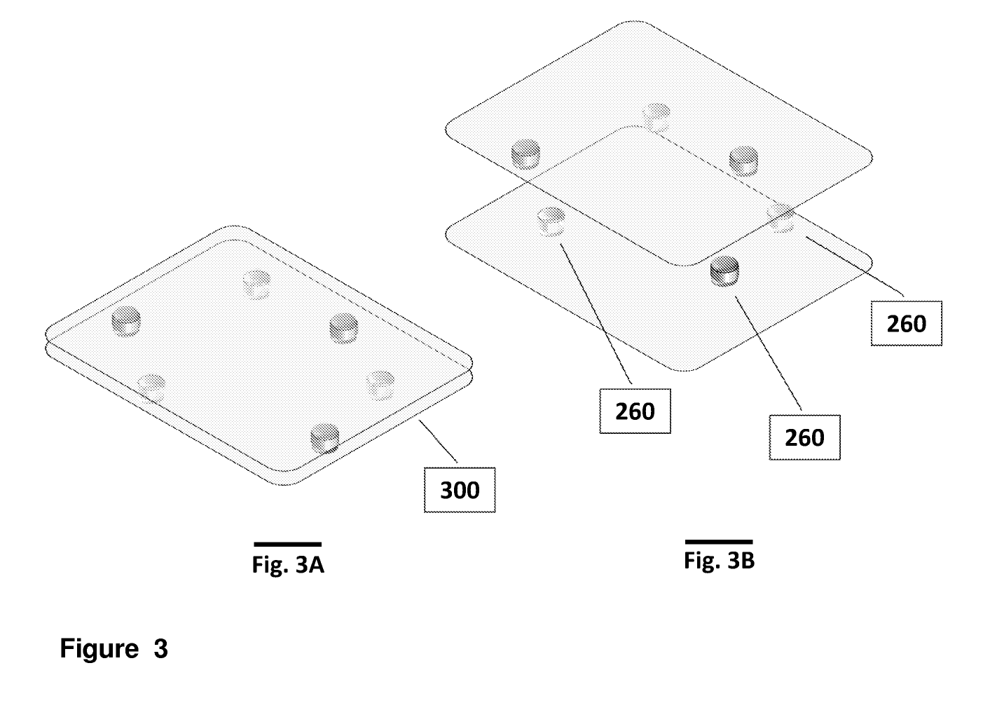

FIG. 3A is a perspective view of an integrated set 300 of plurality of sensing-mounts 260 arrayed randomly on a flexible suspension. FIG. 3B is an exploded view of the randomly arrayed sensing-mounts 260 of FIG. 3A. The random pattern of sensing-mounts 260 may be used where spacing of the mounts in regular distances may be problematic. However, one of ordinary skill in the art readily recognizes that the sensing-mounts can be positioned in a variety of ways and that would be within the spirit and scope of the present invention. Individual sensing-mounts 260 and 230, capacitive parallel-plate and multi-plate are depicted in FIGS. 2A and 2B as examples and without limitation.

A Perimeter Mount sensing-mount suspension is a layer (or layers) of flexible polymer material fabricated or die-cut as a perimeter suspension member that acts upon the perimeter or edge surfaces of the touch surface. The sensing-mount may suspend or hang the touch surface from its host device bezel, or float the touch surface upon or within the host device. The perimeter sensing-mount most commonly might be a continuous strip of material that is die-cut to dimensions of a host-display perimeter, but could also be fabricated of a plurality of strip suspension members.

A perimeter sensing-mount innately supports the touch surface at an infinite number of points while serving in an embodiment as single-member suspension. A perimeter sensing-mount integrates at least three sensing locations or sensing members along said perimeter to enable locating a touch.

A laminar sensing-mount is a full-coverage, full-surface layer (or layers) of flexible polymer material fabricated as a sensing-mount module beneath the touch surface that “floats” the touch surface. A laminar sensing-mount innately supports the touch surface at an infinite number of points while serving as a single-member suspension, a suspension pad. A laminar sensing-mount must also integrate at least three sensing locations or sensing members within said single-member suspension to enable locating a touch. Said integrated sensing-suspension pad can be described as a floating sensor pad.

Enumeration of suspension methods as discrete mounts, perimeter mount or laminar mount are delineated as common implementations. Those skilled in the art will recognize that touch surface embodiments can also be implemented with several small sensor pads, or with edge strips along perimeter locations, as examples and without limitation, still within the spirit and scope of the present invention.

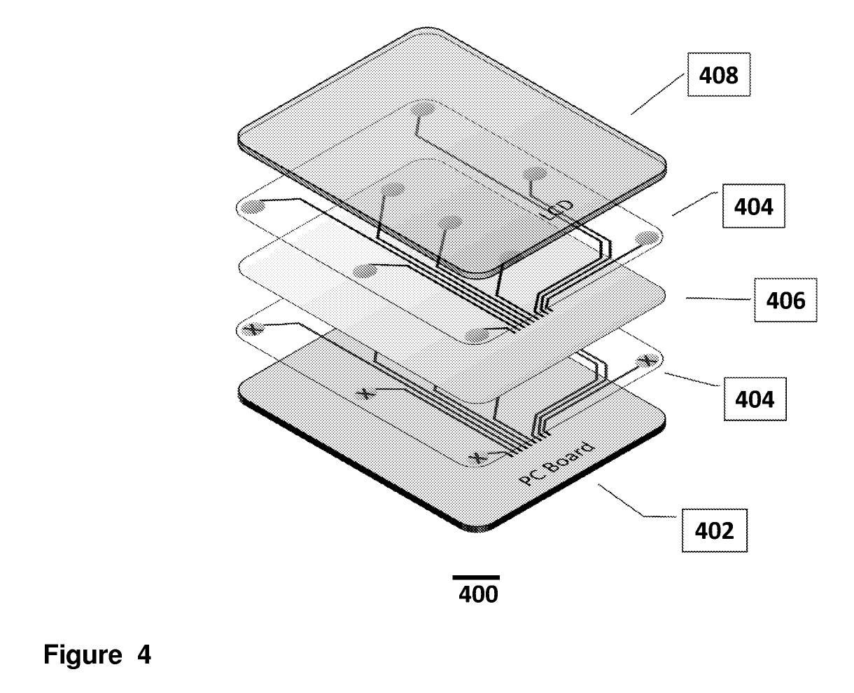

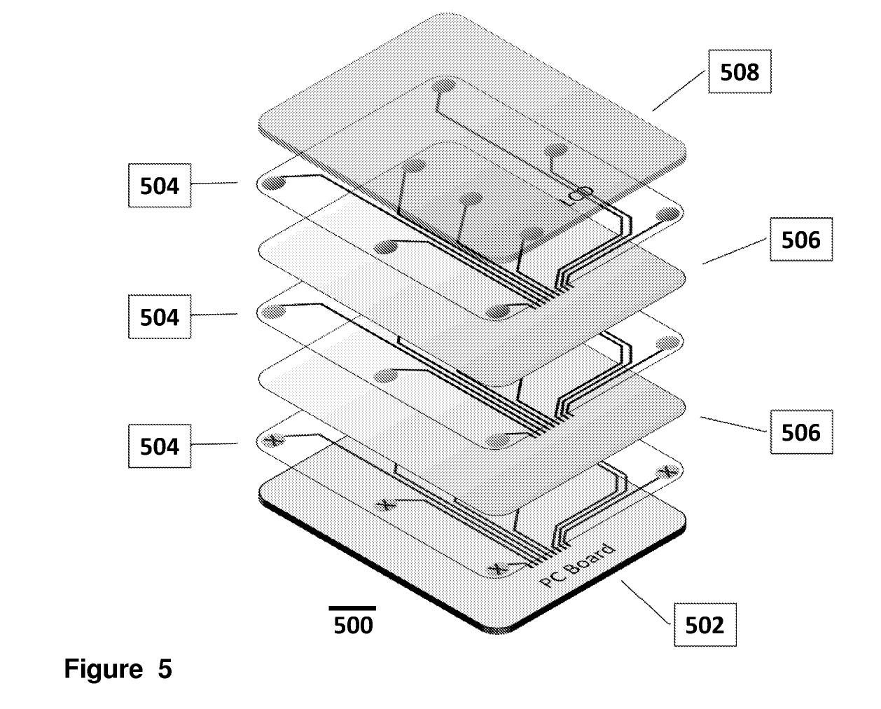

FIG. 4 is an exploded view of a first embodiment of a sensing-module 400 that employs parallel-plate capacitance for motion detection. FIG. 5 is an exploded view of a second embodiment of a sensing-module 500 that employs multi-plate capacitance for motion detection.

In both of these embodiments, a thin, full-surface sheet 406,506 of a polymer is bonded to the touch surface 408,508 and to a lower, interior base surface of the host device 402,502. This sheet mount 406,506 is (again, but without limitation) shown sandwiched between upper and lower flex circuits 404,504 thereby comprising an integrated floating sensing-mount module or pad. In an alternative approach, the sheet mount 406,506 may be stenciled with conductive ink in a circuit design, as a floating sensing-mount module or pad. In an another alternative approach, it is likely that the lower interior base could be a PCB, in which case the lower circuit could actually be “circuit traces” embedded onto the PCB. The circuit traces could be made of any conductive material such as copper, aluminum or the like. All of these alternatives represent a broad design approach to address the varying demands of host industrial designs.
The sheet 406 employs a flexible polymer that is formulated to possess certain attributes:
To float (position, attach and motion-enable) a touch surface within its host device in a fluidic manner,
while also minimizing or eliminating lateral touch friction (X-Y sheer-force vectors) and redirecting said vectors into the Z-axis,
with “flow” characteristic that conforms to slight surface irregularities, and/or planar deficiencies,
And may synergistically contribute to the sensing function via permittivity, permeability, inductance, magnetism, thermal, optical, acoustic properties, etc.

The “attachment” function may be accomplished by various means, including without limitation, mechanical, friction, adhesion, etc.

The suspension function of the suspension material or suspension components provides at least the following properties: a) the ability to deform in response to any force on the touch surface (fluidity); b) the propensity to recover from each deformation (resilience); and c) the ability to compensate for unwanted lateral sheer vectors (redirection).

### Integrated Sensing-Mounts

A uniquely adapted flexible polymer may be fabricated as an integrated “sensor and mount” so that it simultaneously positions, attaches and motion-enables, or “floats” a touch input surface and also senses its movements, resulting in the floating sensing-mount. Therefore, a sensing framework is integrated with the flexible mounting system to detect changes in the displacement of the touch surface relative to the host device. Such relative changes to the touch surface are detected and measured for determining the location of a touch. The sensing array may be variously configured as most appropriate for varying industrial designs of host devices.

Embodiments employ a flexible polymeric mounting material that accommodates surfaces that are not precisely coplanar because the mounting material's flow property innately compensates for minor warping or bending of either plane. This accommodation eases the manufacturing process and enables automatic calibration of the sensing array regardless of minor deviations in height among sensor locations.

Embodiments employ a flexible polymeric mounting material that damps shock and vibration that could otherwise cause stray, unwanted manifestations of a false touch on the touch surface.

Any among a plurality of sensing technologies can be integrated with the floating suspension to detect and measure changes in touch surface displacement, including capacitive, inductive, magnetic, thermal, optical, acoustic or other sensing of the electromagnetic spectrum without limitation.

Embodiments may employ any appropriate sensor technology between the touch surface and host device including two-plate capacitance, multi-plate capacitance, inductance, or any other sensor technology the host industrial design may dictate. Strain detection embodiments may employ appropriate sensor technologies to measure the changes that a mounting material has been formulated to physically express, including without limitation changes in opacity, color, heat, or sound, without limitation.

Appropriately formulated flexible polymeric materials may undergo decipherable internal strain changes during the stress of a touch event. Among these could be changes in temperature, electrical potential, transparency, etc. This fact yields the potential of employing the suspension material itself to synergistically serve in the sensing function, by the measurement of those internal changes, which is denoted as unique to this invention.

A sensing-mount is a flexible polymer that is integrated with any electromagnetic sensing technology that is appropriate to the mounting material formulation and effective for the host environment.

Embodiments detect motion of the touch surface directly as the distance changes at each sensing-mount, or as strain manifestations induced by motion at each sensing-mount.

In the inductive case, a sensing-mount might have a flat plate opposed to a coiled trace.

In the Hall-effect case, a sensing-mount might have a magnet opposed to a Hall-effect sensor.

In the optical case, a sensing-mount might have a mirrored surface opposed to a light source for detecting changes in distance, or color, or opacity.

In the thermal sensing case, a sensing-mount could have a thermocouple probe.

In an embodiment, a floating sensor pad is a pre-manufactured sub-assembly, a flexible template or modular mounting pad that integrates a precisely placed array of sensing-mounts. The array of sensing-mounts can be customized and configured as most appropriate for the industrial design of each host device.

### Pressure Gestures

The present invention uses Z-axis changes to locate a touch. Accordingly, Z-axis changes may be used to interpret one-touch pressure-gestures as user commands. A pressure-gesture consists of a pressure touch of “notably heavy” Z-pressure chained to an immediately following gesture movement. Such single-touch gestures are enabled by employing the Z-vector reading as an additional (third) user input, and thereby enabling command gestures with any touch means, finger, glove or stylus, etc.

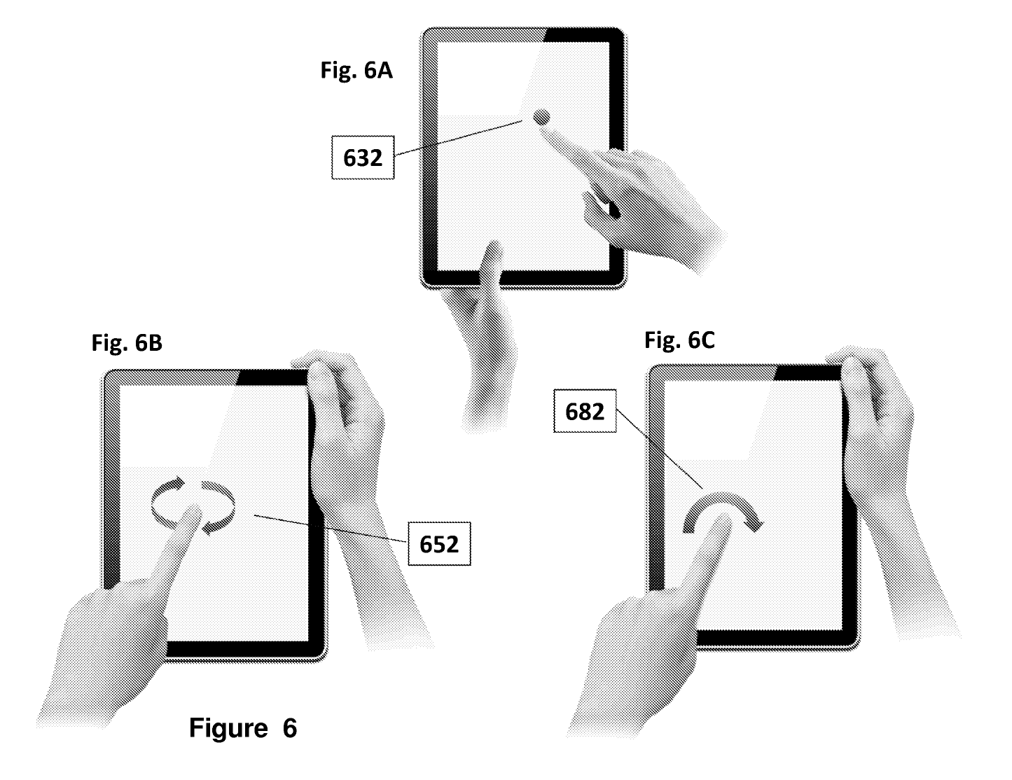

One-touch pressure-gestures are shown in FIG. 6A-6C, without limitation, as a heavy pressure touch 632 followed immediately by a circular gesture 652, which chained gesture indicates a user command to zoom the screen element so touched. The command may be user-designated, within user software, to zoom-in or zoom-out by either circular direction, clockwise or counter-clockwise.

Another command pressure-gesture is a heavy pressure touch 632 followed immediately by an arcing gesture 682, which chained gesture indicates a user command to rotate the screen element so touched. The rotate command re-orients the touched screen element by 90 degrees.

Embodiments also permit multi-touch pressure-gestures as user commands, consisting of a pressure-touch immediately followed by a related pressure-touch, such dual-touch gestures being enabled by employing the immediately chained third-axis (Z-vector) readings of user input. As an example without limitation, heavy pressure by alternating thumbs, one of each hand, can be interpreted in software as a user-designated command.

### Locating System

The locating system comprises a microcontroller and firmware within, for example, the host device 402 of FIG. 4, to interpret readings from the sensing-mount system. In one embodiment, voltage changes are continuously detected and transmitted to the locating system, and then digitized and analyzed to locate the position of each touch. Alternate sensing technologies may deliver alternate change-metrics, without limitation, and still be employed in the sensing-mount system. The calculated touch position is ultimately reported to the host system. A well-known algorithm for locating a touch in a force-based touch system was described in U.S. Pat. No. 4,389,711, and is widely used within the field.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner, as would be apparent to one of ordinary skill in the art from this disclosure, in one or more embodiments.

Thus, while there has been described what is believed to be among preferred embodiments of the invention, those skilled in the art will recognize that other and further modifications may be made thereto without departing from the spirit of the invention, and it is intended to claim all such changes and modifications as fall within the scope of the invention.

We claim:

1. A sensing-mount for use on a touch input device comprising:
at least one suspension member; and
one or more conductive members coupled to the suspension member, wherein an electromagnetic sensor is formed.

2. The sensing-mount of claim 1, wherein the electromagnetic sensor comprises any of a capacitive sensor, inductive sensor, a Hall effect sensor, optical sensor, and thermal sensor.

3. The sensing-mount of claim 1 wherein at least two conductive members are adhesively coupled to the suspension member.

4. The sensing-mount of claim 1 wherein the at least one suspension member allows for floating a touch surface within a host device in a fluidic manner and redirects the sheer force vectors into the Z-axis.

5. The sensing-mount of claim 1 includes flow characteristics that conform to irregularities, and/or planar deficiencies.

6. The sensing-mount of claim 1 wherein at least two conductive members are formed from copper or aluminum.

7. A touch input device comprising:
a touch plane;
a mounting fixture;
a suspension system attached between the touch plane and mounting fixture; and
a means to detect a touch location on the touch plane from movement of the touch plane relative to the mounting fixture.

8. The touch input device of claim 7, where the suspension system includes an array of sensing-mounts.

9. The touch input device of claim 7 wherein each of the array of sensing-mounts comprises:
at least one suspension member; and
one or more conductive members coupled to the suspension member; wherein an electromagnetic sensor is formed.

10. The touch input device of claim 9 wherein the one or more conductive members are adhesively coupled to the suspension member.

11. The touch input device of claim 9 wherein the at least one suspension member allows for floating a touch surface within a host device in a fluidic manner, and redirects the sheer force vectors into the Z-axis.

12. The touch input device of claim 9 wherein the suspension member includes flow characteristics that conforms to irregularities, and/or planar deficiencies.

13. The touch input device of claim 9 wherein at least two conductors are formed from a conductive metal.

14. The touch input device of claim 9 wherein at least two conductors are circuit traces.

15. The touch input device of claim 9 wherein at least two conductors are stenciled with conductive ink onto the suspension member.

16. The touch input device of claim 10, where the sensing-mounts are disposed at a plurality of locations on the suspension system.

17. The touch input device of claim 10, where the sensing-mounts are disposed randomly at a plurality of locations on the suspension system.

18. The touch input device of claim 10, where the sensing-mounts are disposed in a predetermined pattern at a plurality of locations on the suspension system.

19. The touch input device of claim 9 wherein one touch pressure gestures are utilized.

20. The touch input device of claim 19 wherein the one touch pressure gestures can be provided by the touching of any object to the touch plane.

21. A suspension system comprising:
an array of sensing-mounts, wherein the array of sensing-mounts comprises:
at least one suspension member; and
one or more conductive members coupled to the suspension member; wherein an electromagnetic sensor is formed.

22. The suspension system of claim 21 wherein the one or more conductive members are adhesively coupled to the suspension member.

23. The suspension system of claim 21 wherein the at least one suspension member allows for floating a touch surface within a host device in a fluidic manner, minimizes lateral touch friction (X-Y sheer-force vectors) and redirects the sheer force vectors into the Z-axis.

24. The suspension system of 21 wherein the suspension member includes flow characteristics that conforms to irregularities, and/or planar deficiencies.

25. The suspension system of claim 21 wherein at least two conductors are formed from a conductive metal.

26. The suspension system of claim 21 wherein at least two conductors are circuit traces.

27. The suspension system of claim 21 wherein at least two conductors are stenciled with conductive ink onto the suspension member.

28. The suspension system of claim 21, where the sensing-mounts are disposed at a plurality of locations on the suspension system.

29. The suspension system of claim 21, where the sensing-mounts are disposed randomly at a plurality of locations on the suspension system.

30. The suspension system of claim 21, where the sensing-mounts are disposed in a predetermined pattern at a plurality of locations on the suspension system.
